(19) United States
(12) Patent Application Publication
(10) Pub. No.: US 2023/0352317 A1
(43) Pub. Date: Nov. 2, 2023

(54) METHOD FOR MANUFACTURING SEMICONDUCTOR DEVICE AND SEMICONDUCTOR DEVICE

(71) Applicant: LING-YI CHUANG, Hefei (CN)

(72) Inventor: LING-YI CHUANG, Hefei (CN)

(21) Appl. No.: 17/897,268

(22) Filed: Aug. 29, 2022

(30) Foreign Application Priority Data
Apr. 27, 2022 (CN) 202210459337.3

(51) Int. Cl. H01L 23/29; H01L 23/00; H01L 25/065; H01L 23/31; H01L 21/56

(52) U.S. Cl. CPC H01L 21/561; H01L 21/568; H01L 23/291; H01L 23/3135; H01L 24/08; H01L 24/13; H01L 24/80; H01L 24/94; H01L 24/96; H01L 24/97; H01L 25/0657; H01L 2224/08145; H01L 2224/13147; H01L 2224/80895; H01L 2224/80896; H01L 2224/95001; H01L 2225/06524; H01L 2225/06541; H01L 2225/06589; H01L 2924/1431; H01L 2924/1436; H01L 2924/1811; H01L 2924/182; H01L 2924/186; H01L 2924/37001

(57) ABSTRACT

A method for manufacturing a semiconductor device and a semiconductor device are provided. The method includes: providing a carrier; providing multiple wafers each including multiple chips; stacking the multiple wafers on the carrier sequentially in a vertical direction, and bonding the chips respectively disposed on two adjacent ones of the wafers in a one-to-one correspondence; performing a first cutting process on the multiple wafers to form multiple cutting slots located above the carrier and penetrating through the multiple wafers to divide the multiple wafers into multiple chip stacks each including multiple chips stacked in the vertical direction, and the carrier enabling the chip stacks to be in an un-separated state; forming a cladding layer covering at least one chip stack; and performing a second cutting process on the cladding layer along the cutting slots to form multiple chip stacks covered with the cladding layer.

### CROSS-REFERENCE TO RELATED APPLICATIONS

This application is a continuation application of International Application No. PCT/CN2022/093545, filed on May 18, 2022, which claims priority to Chinese Patent Application No. 202210459337.3, filed on Apr. 27, 2022. The disclosures of International Application No. PCT/CN2022/093545 and Chinese Patent Application No. 202210459337.3 are hereby incorporated by reference in their entireties.

### BACKGROUND

With the development of miniaturization, high integration and multifunction of semiconductor devices, the problems of stability and reliability during the use have attracted extensive attention. As an indispensable stage of forming a semiconductor device, a process for manufacturing a semiconductor device is directly related to the performance of stability and reliability of the finally formed semiconductor device during the use.

However, in the current process for manufacturing a semiconductor device, there are still many shortcomings, and how to optimize the process is an urgent technical problem to be solved at this stage.

### SUMMARY

The disclosure relates to the field of semiconductor manufacturing, and in particular, to a method for manufacturing a semiconductor device and a semiconductor device.

Embodiments of the disclosure provide a method for manufacturing a semiconductor device. The method includes the following operations.

A carrier is provided.

Multiple wafers each including multiple chips are provided.

The multiple wafers are stacked on the carrier sequentially in a vertical direction, and the chips respectively disposed on two adjacent ones of the wafers are bonded in a one-to-one correspondence.

A first cutting process is performed on the multiple wafers to form multiple cutting slots located above the carrier and penetrating through the multiple wafers, in which the multiple wafers are divided into multiple chip stacks by the cutting slots, each of the chip stacks include multiple chips stacked in the vertical direction, and the carrier enables the multiple chip stacks to be in an un-separated state.

A cladding layer covering a side wall and an upper surface of at least one chip stack is formed.

A second cutting process is performed on the cladding layer along the cutting slots to form multiple chip stacks having side walls and upper surfaces covered with the cladding layer.

The embodiments of the disclosure also provide a semiconductor device. The semiconductor device includes a logic chip, a chip stack and a cladding layer.

The chip stack includes multiple chips stacked on the logic chip in a vertical direction, and two adjacent ones of the chips are connected with each other, in which the chip stack is formed by performing a cutting process on multiple wafers vertically stacked.

The cladding layer is located above the logic chip and covers a side wall and an upper surface of the chip stack.

The details of one or more embodiments of the disclosure are set forth in the drawings and the description below. Other features and advantages of the disclosure will be apparent from the drawings and the claims from the specification.

### BRIEF DESCRIPTION OF THE DRAWINGS

In order to more clearly illustrate the technical solutions in the embodiments of the disclosure, the drawings used in the technical description of the embodiments will be briefly described below. It is apparent that the drawings in the following descriptions are merely some embodiments of the disclosure. Other drawings can be obtained from those skilled in the art according to these drawings without any creative work.

FIG. 1 is a block flowchart of a method for manufacturing a semiconductor device according to an embodiment of the disclosure.

FIGS. 2, 3, 4A-4C, and 5A-5C are diagrams of process flow in a manufacturing process of a semiconductor device according to an embodiment of the disclosure.

FIG. 6 is a three-dimensional structure diagram of multiple wafers stacked on a carrier according to an embodiment of the disclosure.

FIG. 7 is a process diagram of a first cutting process performed on a semiconductor device according to an embodiment of the disclosure.

FIGS. 8A and 8B are a top view and a partial cross-sectional view, respectively, of a semiconductor device according to an embodiment of the disclosure after performing a first cutting process.

FIGS. 9A-9B and 10A-10C are diagrams of process flow of forming a cladding layer on a semiconductor device according to different embodiments of the disclosure.

FIG. 11 is a cross-sectional view of a chip stack formed after performing a second cutting process on a semiconductor device according to an embodiment of the disclosure.

FIGS. 12-14 are diagrams of process flow of bonding a chip stack to a logic wafer according to an embodiment of the disclosure.

FIG. 15 is a cross-sectional view of a structure formed after bonding a chip stack to a logic wafer according to an embodiment of the disclosure.

FIG. 16 is a cross-sectional view of another structure formed after bonding a chip stack to a logic wafer according to an embodiment of the disclosure.

FIG. 17 is a cross-sectional view of yet another structure formed after bonding a chip stack to a logic wafer according to an embodiment of the disclosure.

FIG. 18 is a cross-sectional view of a structure of a semiconductor device according to an embodiment of the disclosure after formation of an encapsulation compound.

FIG. 19 is a cross-sectional view of another structure of a semiconductor device according to an embodiment of the disclosure after formation of an encapsulation compound.

### DETAILED DESCRIPTION

Exemplary embodiments disclosed in the disclosure are described in more detail with reference to drawings. Although the exemplary embodiments of the disclosure are shown in the drawings, it should be understood that the disclosure may be implemented in various forms and should not be limited by the specific embodiments described here. On the contrary, these embodiments are provided for more thorough understanding of the disclosure, and to fully convey a scope disclosed in the embodiments of the disclosure to a person skilled in the art.

In the following descriptions, a lot of specific details are given in order to provide the more thorough understanding of the disclosure. However, it is apparent to a person skilled in the art that the disclosure may be implemented without one or more of these details. In other examples, in order to avoid confusion with the disclosure, some technical features well-known in the field are not described. Namely, all the features of the actual embodiments are not described here, and well-known functions and structures are not described in detail.

In the drawings, the sizes of a layer, a region, and an element and their relative sizes may be exaggerated for clarity. The same reference sign represents the same element throughout.

It should be understood that while the element or the layer is referred to as being “on”, “adjacent to”, “connected to” or “coupled to” other elements or layers, it may be directly on the other elements or layers, adjacent to, connected or coupled to the other elements or layers, or an intermediate element or layer may be existent. In contrast, while the element is referred to as being “directly on”, “directly adjacent to”, “directly connected to” or “directly coupled to” other elements or layers, the intermediate element or layer is not existent. It should be understood that although terms first, second, third and the like may be used to describe various elements, components, regions, layers and/or sections, these elements, components, regions, layers and/or sections should not be limited by these terms. These terms are only used to distinguish one element, component, region, layer or section from another element, component, region, layer or section. Therefore, without departing from the teaching of the disclosure, a first element, component, region, layer or section discussed below may be represented as a second element, component, region, layer or section. While the second element, component, region, layer or section is discussed, it does not mean that the first element, component, region, layer or section is necessarily existent in the disclosure.

Spatial relation terms, such as “under”, “below”, “lower”, “underneath”, “above”, “upper” and the like, may be used here for conveniently describing so that a relationship between one element or feature shown in the drawings and other elements or features is described. It should be understood that in addition to orientations shown in the drawings, the spatial relationship terms are intended to further include the different orientations of a device in use and operation. For example, if the device in the drawings is turned over, then the elements or the features described as “below” or “underneath” or “under” other elements may be oriented “above” the elements or features. Therefore, the exemplary terms “below” and “under” may include two orientations of up and down. The device may be otherwise oriented (rotated by 90 degrees or other orientations) and the spatial descriptions used here are interpreted accordingly.

A purpose of the terms used here is only to describe the specific embodiments and not as limitation to the disclosure. While used here, singular forms of “a/an”, “one” and “said/the” are also intended to include plural forms, unless the context clearly indicates another mode. It should also be understood that terms “composition” and/or “include/comprise”, while used in the description, determine the existence of the described features, integers, steps, operations, elements and/or parts, but do not exclude the existence or addition of one or more other features, integers, steps, operations, elements, parts, and/or groups. As used herein, a term “and/or” includes any and all combinations of related items listed.

With the development and progress of technology, the size of semiconductor devices is further reduced and the degree of integration is increasing. However, in addition to the above-mentioned changes, the performances of stability and reliability of semiconductor devices during the use become increasingly concerned problems. For example, how to balance the problem of heat dissipation while reducing the size, and how to balance the problem of low transmission rate due to increase of the height of a contact point which is for solving the problem of heat dissipation, etc.

Based on this, the following technical solutions of the embodiments of the disclosure are provided.

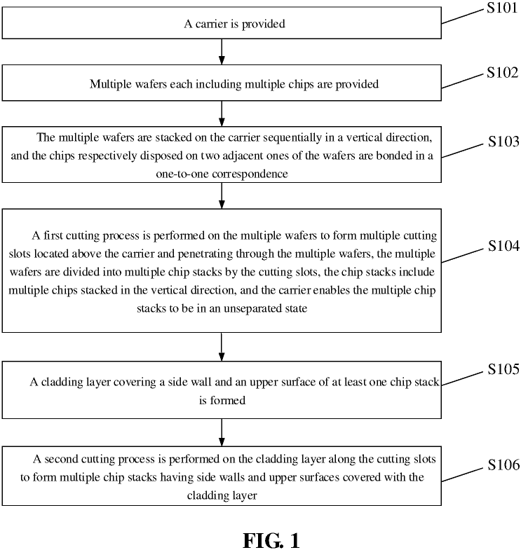

An embodiment of the disclosure provides a method for manufacturing a semiconductor device. As shown in FIG. 1, the method includes the following steps.

In S101, a carrier is provided.

In S102, multiple wafers each including multiple chips are provided.

In S103, the multiple wafers are stacked on the carrier sequentially in a vertical direction, and the chips respectively disposed on adjacent ones of the wafers are bonded in a one-to-one correspondence.

In S104, a first cutting process is performed on the multiple wafers to form multiple cutting slots located above the carrier and penetrating through the multiple wafers, the multiple wafers are divided into multiple chip stacks based on the cutting slots, the chip stacks include multiple chips stacked in the vertical direction, and the carrier enables the multiple chip stacks to be in an un-separated state.

In S105, a cladding layer covering a side wall and an upper surface of at least one chip stack is formed.

In S106, a second cutting process is performed on the cladding layer along the cutting slots to form multiple chip stacks having side walls and upper surfaces covered with the cladding layer.

In the embodiment of the disclosure, multiple wafers are stacked and bonded on a carrier, and then the first cutting process is performed; at this time, only the multiple wafers are cut through without cutting off the carrier to form multiple chip stacks in an un-separated state.; next, the cladding layer is formed on the chip stacks, which is formed so as to encapsulate and fix substances such as particles which are generated when the first cutting process is performed, on the side walls and the upper surfaces of the chip stack, thereby preventing the semiconductor device finally formed from inclination or the risk of poor contact due to movement of the substances during subsequent transfer or encapsulation process. Finally, a second cutting process is performed on the cladding layer to form multiple chip stacks having side walls and upper surfaces covered with the cladding layer. Therefore, the method for manufacturing a semiconductor device provided by the embodiment of the disclosure can significantly improve the stability and reliability of the semiconductor device finally formed. In addition, the operation of the first cutting process without cutting off the carrier in the embodiment of the disclosure provides the possibility that the cladding layer is simultaneously formed on the side walls and the upper surfaces of the multiple chip stacks, which optimizes the process flow, and effectively improves the production efficiency.

In order to make the above purposes, features and advantages of the disclosure more obvious and easy to understand, specific implementations of the disclosure are described below in detail with reference to the drawings. While the embodiments of the disclosure are described in detail, for ease of descriptions, a schematic diagram may not be partially enlarged according to a general scale, and the schematic diagram is only an example, it should not limit a scope of protection of the disclosure herein.

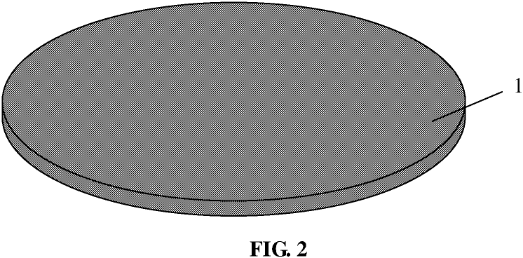

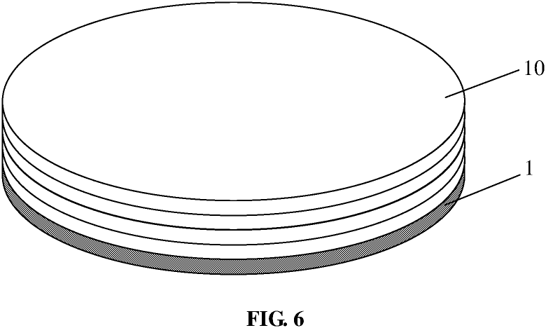

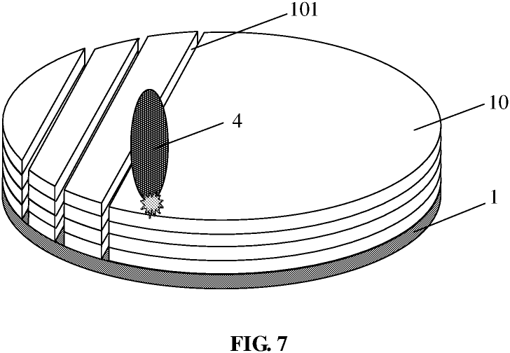

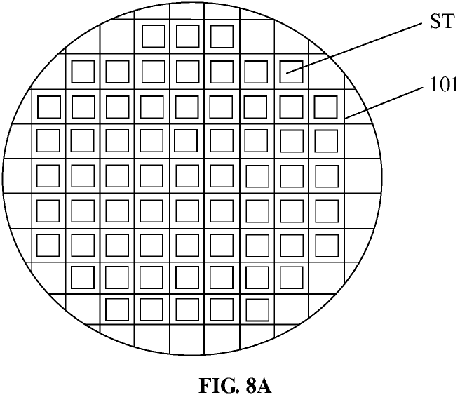

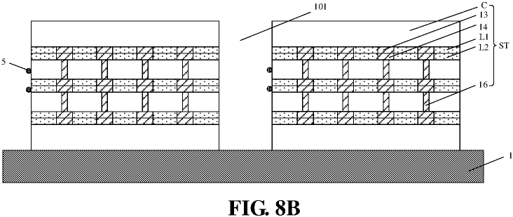

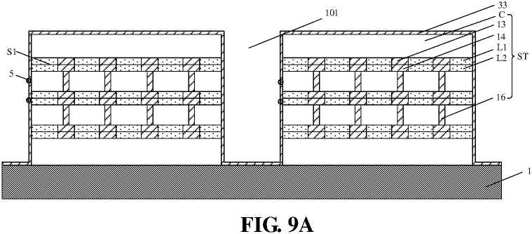

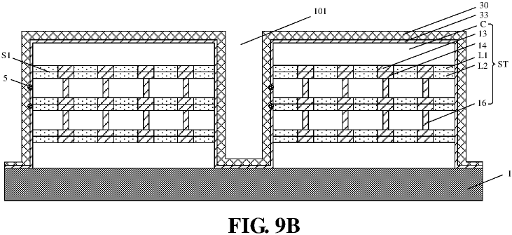

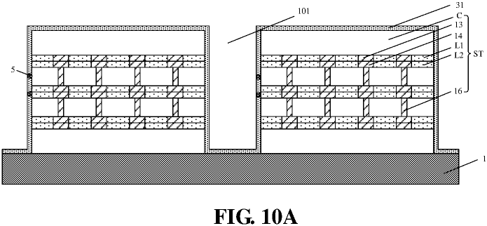

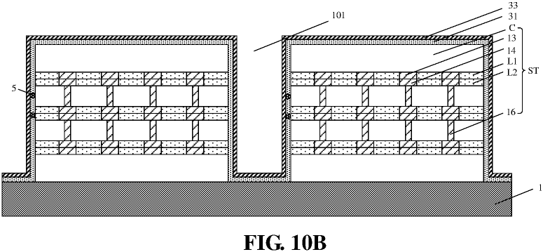

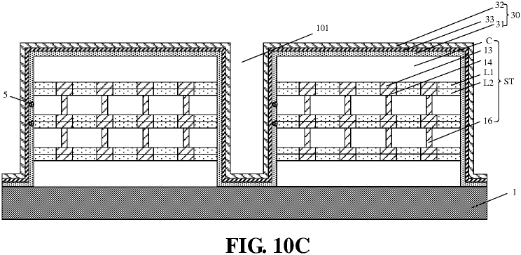

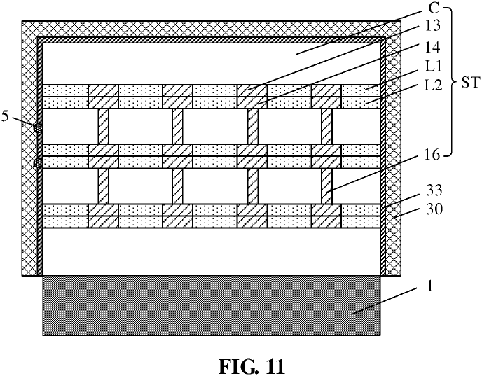

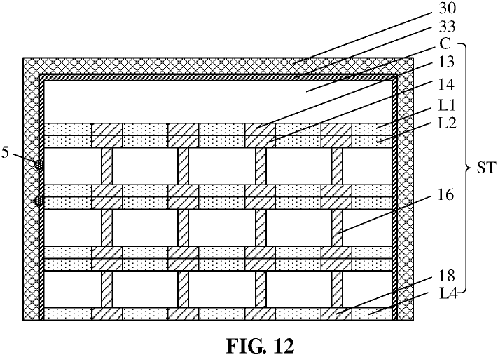

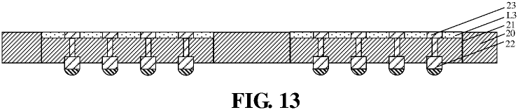

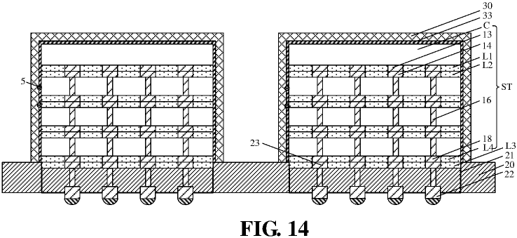

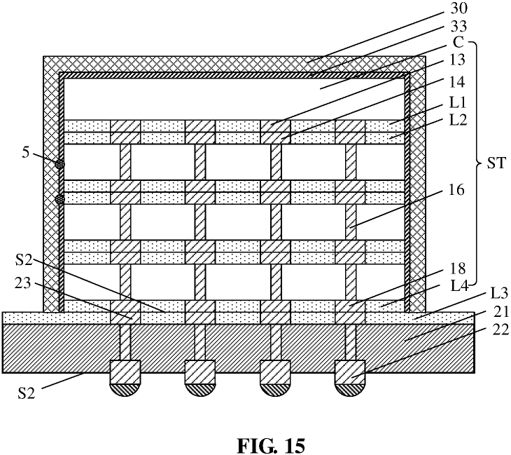

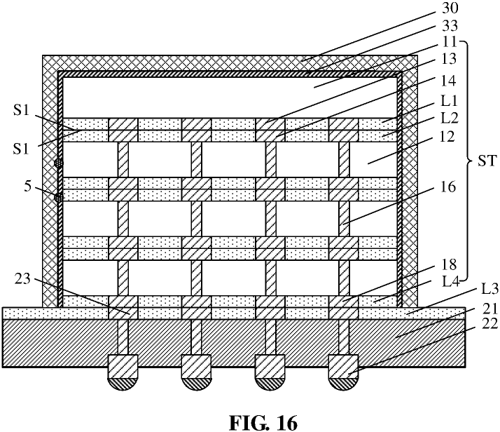

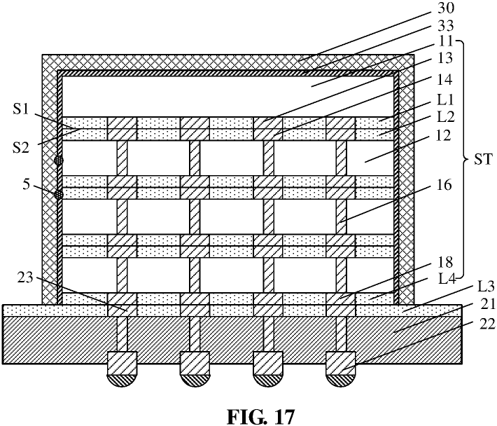

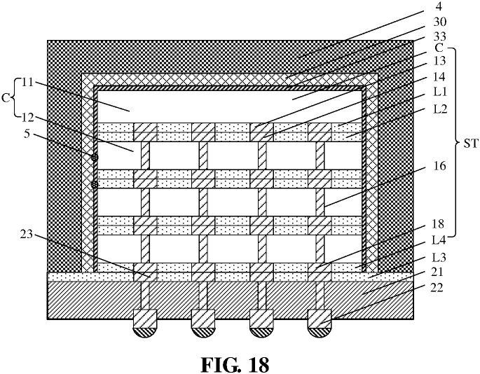

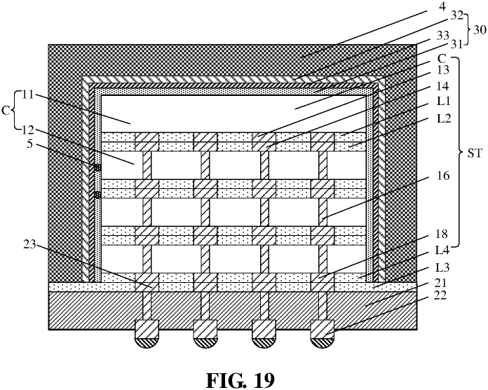

FIG. 1 is a block flowchart of a method for manufacturing a semiconductor device according to an embodiment of the disclosure. FIGS. 2, 3, 4A-4C, and 5A-5C are diagrams of process flow in a manufacturing process of a semiconductor device according to an embodiment of the disclosure. FIG. 6 is a three-dimensional structure diagram of multiple wafers stacked on a carrier according to an embodiment of the disclosure. FIG. 7 is a process diagram of a first cutting process performed on a semiconductor device according to an embodiment of the disclosure. FIGS. 8A and 8B are a top view and a partial cross-sectional view, respectively, of a semiconductor device according to an embodiment of the disclosure after performing a first cutting process. FIGS. 9A-9B and 10A-10C are diagrams of process flow of forming a cladding layer on a semiconductor device according to different embodiments of the disclosure. FIG. 11 is a cross-sectional view of a chip stack formed after performing a second cutting process on a semiconductor device according to an embodiment of the disclosure. FIGS. 12-14 are process flow of bonding a chip stack to a logic wafer according to an embodiment of the disclosure. FIG. 15 is a cross-sectional view of a structure formed after bonding a chip stack to a logic wafer according to an embodiment of the disclosure. FIG. 16 is a cross-sectional view of another structure formed after bonding a chip stack to a logic wafer according to an embodiment of the disclosure. FIG. 17 is a cross-sectional view of yet another structure formed after bonding a chip stack to a logic wafer according to an embodiment of the disclosure. FIG. 18 is a cross-sectional view of a structure of a semiconductor device according to an embodiment of the disclosure after formation of an encapsulation compound. FIG. 19 is a cross-sectional view of another structure of a semiconductor device according to an embodiment of the disclosure after formation of an encapsulation compound.

Hereinafter, a method for manufacturing a semiconductor device according to an embodiment of the disclosure will be described in further detail with reference to the accompanying drawings.

Firstly, S101 is performed. As shown in FIG. 2, a carrier 1 is provided.

In some embodiments, a material of the carrier 1 may include, but is not limited to, a waste wafer, a glass substrate, a semiconductor substrate, or a ceramic substrate, etc.

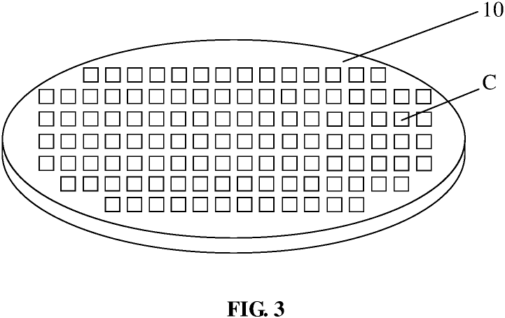

Next, S102 is performed. As shown in FIG. 3, multiple wafers 10 are provided. Each of the wafers 10 includes multiple chips C.

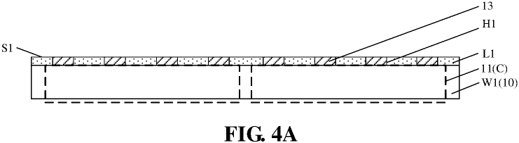

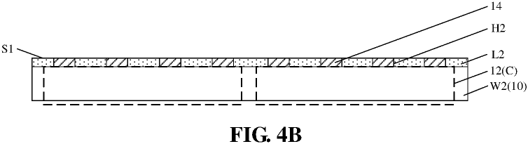

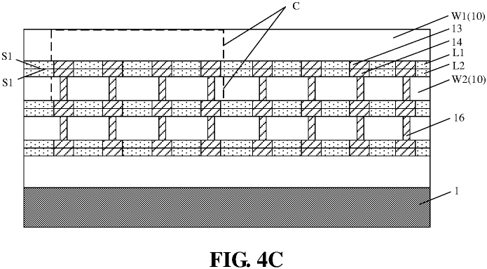

Next, S103 is performed. As shown in FIGS. 4A-4C, FIGS. 5A-5C, and FIG. 6, the multiple wafers 10 are stacked on the carrier 1 sequentially in a vertical direction, and the chips C respectively disposed on adjacent wafers 10 are bonded in a one-to-one correspondence.

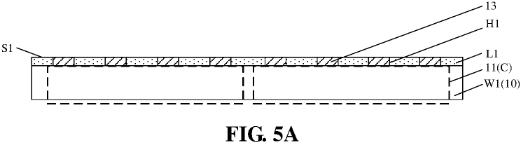

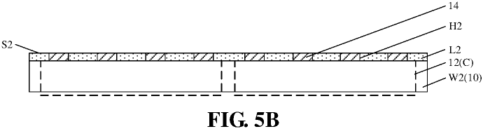

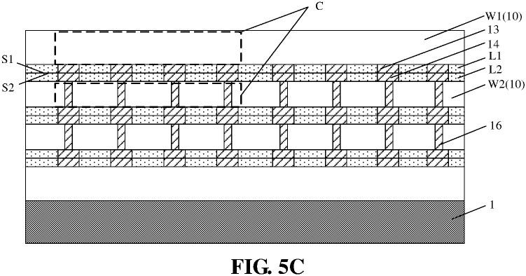

FIGS. 4A-4C and 5A-5C are partial cross-sectional views of stacking the multiple wafers 10 on the carrier 1 sequentially in the vertical direction.

As shown in FIGS. 4A-4C and 5A-5C, in some embodiments, the operation of providing multiple wafers 10 each including multiple chips includes the following operation.

A first wafer W1 and a second wafer W2 are provided. The first wafer W1 includes multiple first chips 11, and the second wafer W2 includes multiple second chips 12.

The operation of stacking the multiple wafers 10 on the carrier 1 sequentially in a vertical direction and bonding the chips C respectively disposed on adjacent wafers 10 in a one-to-one correspondence includes the following operations.

At least one first contact pad 13 and at least one second contact pad 14 are formed on the surfaces of the first wafer W1 and the second wafer W2, respectively, and a first dielectric layer L1 located on the periphery of the first contact pad 13 and a second dielectric layer L2 located on the periphery of the second contact pad 14 are formed.

The first wafer W1 and the second wafer W2 are stacked above the carrier 1 sequentially so that the first contact pad 13 and the second contact pad 14 are butted.

A bonding process is performed so that the first contact pad 13 and the second contact pad 14 are bonded and the first dielectric layer L1 and the second dielectric layer L2 are bonded to form a hybrid bonding member.

In a practical process, a material of the first dielectric layer includes, but is not limited to, oxide, nitride, oxynitride, etc. A material of the second dielectric layer may also include, but is not limited to, oxide, nitride, oxynitride, etc. Materials of the first contact pad and the second contact pad include, but are not limited to, an alloy formed by one or more of copper, gold, silver, aluminum, nickel, tungsten, titanium, tin, conductive graphene, or carbon nanotubes. Here, the materials of the first dielectric layer and the second dielectric layer may be the same. In fact, different materials may be used to form the first dielectric layer and the second dielectric layer, respectively. This is not particularly limited herein. Similarly, the materials of the first contact pad and the second contact pad may be the same or different. This is not particularly limited herein.

It will be appreciated that in this embodiment of the disclosure, compared with a conventional structure using a larger micro-bump for electrical connection, the mode of forming an electrical connection by one-to-one corresponding bonding between the chips of the adjacent wafers by means of hybrid bonding can effectively shorten the wiring distance between the corresponding chips located on the adjacent wafers, whereby the communication distance between the chips is shortened, the signal transmission efficiency can be effectively improved, and the communication time can be shortened.

In some embodiments, as shown in FIGS. 5A-5C, the operation of forming at least one first contact pad 13 and at least one second contact pad 14 on the surfaces of the first wafer W1 and the second wafer W2, respectively, and forming the first dielectric layer L1 located on the periphery of the first contact pad 13 and the second dielectric layer L2 located on the periphery of the second contact pad 14 includes the following operations.

The first dielectric layer L1 is formed on an active surface S1 of the first wafer W1.

At least one first via H1 is formed in the first dielectric layer L1.

The first contact pad 13 is formed in the first via H1, and the first contact pad 13 is connected to the first chip 11 in a one-to-one correspondence.

The second dielectric layer L2 is formed on a non-active surface S2 of the second wafer W2.

At least one second via H2 is formed in the second dielectric layer L2.

The second contact pad 14 is formed in the second via H2, and the second contact pad 14 is connected to the second chip 12 in a one-to-one correspondence. The active surface S1 is a side of the wafer where a device layer is formed, and the non-active surface S2 is an opposite side of the active surface.

In this embodiment of the disclosure, the mode of forming an electrical connection by one-to-one correspondence bonding between the chips of the adjacent wafers by means of hybrid bonding can effectively shorten the gap between the corresponding chips located on the adjacent wafers, whereby the communication distance between the chips is shortened, the signal transmission efficiency can be effectively improved, and the communication time can be shortened.

In other embodiments, as shown in FIGS. 4A-4C, the operation of forming at least one first contact pad 13 and at least one second contact pad 14 on the surfaces of the first wafer W1 and the second wafer W2, respectively, and forming the first dielectric layer L1 located on the periphery of the first contact pad 13 and the second dielectric layer L2 located on the periphery of the second contact pad 14 includes the following operations.

The first dielectric layer L1 is formed on an active surface S1 of the first wafer W1.

At least one first via H1 is formed in the first dielectric layer L1.

The first contact pad 13 is formed in the first via H1, and the first contact pad 13 is connected to the first chip 11 in a one-to-one correspondence.

The second dielectric layer L2 is formed on an active surface S1 of the second wafer W2.

At least one second via H2 is formed on the second dielectric layer L2.

The second contact pad 14 is formed in the second via H2, and the second contact pad 14 is connected to the second chip 12 in a one-to-one correspondence. The active surface S1 is the side of the wafer 10 where a device layer is formed.

Here, the wafer 10 includes the first wafer W1 and the second wafer W2. The chip C includes the first chip 11 and the second chip 12.

In this embodiment, by forming the first dielectric layer and the first contact pad on the active surface of the first wafer and forming the second dielectric layer and the second contact pad on the active surface of the second wafer, hybrid bonding is performed between the two wafers in a face-to-face manner. That is, chips at corresponding positions in adjacent wafers are in a face-to-face hybrid bonding manner between the active surfaces. It can be appreciated that this hybrid bonding and face-to-face bonding mode can further reduce the communication distance between the two adjacent chips, further improve the communication efficiency, and more effectively shorten the communication time as compared to other embodiments.

It should be noted that the disclosure only exemplifies some embodiments for bonding between wafers. In actual operation, the bonding mode between the first wafer and the second wafer, and the positions where the first dielectric layer and the first contact pad, as well as the second dielectric layer and the second contact pad are specifically formed on the first wafer and the second wafer, respectively, may be flexibly adjusted according to actual situations.

In addition, in the figure of this embodiment of the disclosure, a diagram of stacking and bonding four wafers on a carrier is shown by way of example only. The number of the wafers may also be eight, twelve, and even other more or less numbers in an actual process. This is not particularly limited herein. The number of wafers may be flexibly adjusted as required.

Next, S104 is performed. As shown in FIGS. 7, 8A and 8B, a first cutting process is performed on the multiple wafers 10 to form multiple cutting slots 101 located above the carrier 1 and penetrating through the multiple wafers 10. The multiple wafers 10 are divided into multiple chip stacks ST by the cutting slots 101. Each chip stack ST includes multiple chips C stacked in the vertical direction. The carrier 1 enables the multiple chip stacks ST to be in an un-separated state.

With continued reference to FIGS. 7, 8A and 8B, in some embodiments, the operation of performing the first cutting process on the multiple wafers 10 includes the following operation.

The first cutting process is performed on the multiple wafers 10 by using a wafer cutting knife 4 and/or a cutting line to form the multiple cutting slots 101 located above the carrier 1 and penetrating through the multiple wafers 10, and the multiple wafers 10 are divided into multiple chip stacks ST by the cutting slots 101.

Here, the cutting line includes, but is not limited to, a diamond line, etc.

It can be appreciated that in this embodiment, the practice of not cutting off the carrier while performing the first cutting process provides the possibility that the cladding layer may be simultaneously formed on the side walls and the upper surfaces of the multiple chip stacks, which optimizes the process flow, and can effectively improve the production efficiency.

Then, S105 is continuously performed. As shown in FIGS. 9A-9B and FIGS. 10A-10C, a cladding layer 30 is formed. The cladding layer 30 covers a side wall and an upper surface of at least one chip stack ST.

In some embodiments, as shown in FIGS. 9A-9B, the operation of forming the cladding layer 30 includes the following operations.

A seed layer 33 is formed on the chip stack ST, and the seed layer 33 covers the side wall and the upper surface of the chip stack ST. An active surface S1 of the chip C located at the topmost layer of the chip stack ST faces downwards, and the active surface S1 is a side of the wafer where a device layer is formed.

An electroplating process is performed to form the cladding layer 30 on the seed layer 33, covering the seed layer 33.

In some embodiments, the materials of the seed layer and the cladding layer include, but are not limited to, copper, etc. Although not limited thereto, the material of the cladding layer may also be other materials having better thermal conductivity.

In other embodiments, as shown in FIGS. 10A-10C, the operation of forming the cladding layer includes the following operations.

A coating process is performed to form a first sub-layer 31 on the side wall and the upper surface of the chip stack ST.

A seed layer 33 is formed on the first sub-layer 31.

An electroplating process is performed to form a second sub-layer 32 on the seed layer 33, covering the seed layer 33.

Here, the material of the first sub-layer includes, but is not limited to, spin-on glass (SOG), etc. The SOG may be an interlayer dielectric material that is spin-coated (similar to the spin-coating of a photoresist) onto a semiconductor structure in a liquid state. A raw material of the SOG may include, but are not limited to, hydrogen silsesquioxane polymer and siloxane solvent, etc. The materials of the seed layer and the second sub-layer include, but are not limited to, copper, etc. Although not limited thereto, the material of the second sub-layer may also be other materials having better thermal conductivity.

In some embodiments, when the materials of the cladding layer and the second sub-layer are copper, the operation of performing an electroplating process includes the following operations.

The semiconductor device is immersed in an electroplating copper solution, and the semiconductor device includes a seed layer.

An electroplating copper layer is formed on the seed layer. The electroplating copper solution includes, but is not limited to, water, a copper supply source, an electrolyte material, etc.

In an actual process, as can be seen with reference to FIG. 8B, when the cutting process is performed, some particles 5 may be relatively easily generated. The particles 5 may include, but are not limited to, substances such as scraps, powders or the like generated during the production process, and it is difficult to completely remove all these substances even when a cleaning process is performed after the cutting process.

However, in this embodiment of the disclosure, by combining FIGS. 9B and 10C, it can be seen that the cladding layer 30 wraps the particles 5 generated during the first cutting process.

It can be appreciated that in some structures not forming a cladding layer, substances such as these particles often move around, especially in the process of encapsulating and bonding with other functional chips, when these substances move therebetween, it is easy to cause the inclination of the upper chip and even cause the problem of poor contact of the device finally formed, thereby causing chip fault and even failure, and reducing the production yield.

Therefore, in this embodiment of the disclosure, the presence of the cladding layer can effectively prevent the above substances from moving during the subsequent transfer or encapsulation process, in which such movement results in the inclination of the semiconductor device finally formed or a risk of poor contact, thereby improving the stability and reliability of the device finally formed, and contributing to the improvement of the production yield.

In addition, in the conventional semiconductor device using the micro-bump structure, the information transmission rate is easily affected by the heat dissipation condition. When heat inside the semiconductor device cannot be conducted away in time, the information transmission rate of the semiconductor device is reduced, and the communication time is prolonged. Furthermore, as the heat inside the semiconductor device accumulates, the stability and reliability of the semiconductor device are greatly affected.

However, in this embodiment of the disclosure, when the material of the cladding layer includes a metal material or other materials having relatively good thermal conductivity, heat generated inside the semiconductor device during operation may be conducted to the outside of the semiconductor device via the cladding layer. Therefore, in this embodiment of the disclosure, the semiconductor device can avoid the situation that the information transmission rate is reduced and the stability and reliability are reduced due to not timely conduction of heat, and can effectively improve the stability and reliability of the semiconductor device.

It should be noted that when the material of the cladding layer is a conductive material having a good heat dissipation property and the conductive material is in direct contact with the wafer, the active surface of the wafer, i.e. the side of the wafer where a device layer is formed, needs to deviate from the cladding layer.

Finally, S106 is performed. As shown in FIGS. 9B and 11, a second cutting process is performed on the cladding layer 30 along the cutting slots 101 to form multiple chip stacks ST, each having the side walls and upper surface covered with the cladding layer 30.

The operation of performing the second cutting process on the cladding layer 30 along the cutting slots 101 includes the following operation.

The second cutting process is performed on the cladding layer 30 by using a grinding wheel, a wafer cutting knife 4, a cutting line, and/or a laser cutting process to form multiple chip stacks ST, each having the side walls and upper surface covered with the cladding layer 30.

In some embodiments, as shown in FIGS. 12-14, after the second cutting process is performed, the method further includes the following operations.

The carrier 1 is separated from the chip stack ST.

A logic wafer 20 is provided, and the logic wafer 20 includes at least one logic chip 21.

The chip stack ST is bonded to the logic chip 21.

Here, the logic chip 21 may be one or more processors configured to communicate with the multiple chips C to access data from the chips C and store data in the multiple chips C. The logic chip 21 includes, but is not limited to, a graphics processing unit (GPU), a field programmable gate array (FPGA), an application specific integrated circuit (ASIC), a central processing unit (CPU), or other known electronic circuits used as processors. The chip C includes, but is not limited to, a dynamic random access memory (DRAM) chip.

With continued reference to FIGS. 12-14, it can be seen that the operation of bonding the chip stack ST to the logic chip 21 includes the following operations.

At least one third contact pad 23 is formed on the surface of the logic wafer 20, and the third contact pad 23 is connected to the logic chip 21 in a one-to-one correspondence.

A fourth contact pad 18 is formed on a lower surface of the chip C at the bottommost layer of the chip stack ST.

The chip stack ST is arranged above the logic chip 21, and the third contact pad 23 is butted with the fourth contact pad 18.

A bonding process is performed so that the third contact pad 23 and the fourth contact pad 18 are bonded.

In some embodiments, the operation of forming the third contact pad 23 and the fourth contact pad 18 includes the following operations.

A third dielectric layer L3 is formed on the surface of the logic wafer 20.

The third contact pad 23 is formed in the third dielectric layer L3.

A fourth dielectric layer L4 is formed on a lower surface of the chip C at the bottommost layer of the chip stack ST.

The fourth contact pad 18 is formed in the fourth dielectric layer L4.

Here, the materials of the third contact pad 23 and the fourth contact pad 18 may be the same as the materials of the first contact pad 13 and the second contact pad 14. The descriptions thereof are omitted herein.

Optionally, after the chip stack ST is bonded to the logic chip 21, the method further includes: forming multiple copper pillar bumps 22 on the surface of the logic wafer 20 away from the chip stack ST. The copper pillar bumps 22 may be used for forming electrical connections between the semiconductor device and other devices, such as PCB boards.

In some embodiments, as shown in FIGS. 15-17, after the chip stack ST is bonded to the logic wafer 20 including the logic chip 21, the method further includes the following operations.

A third cutting process is performed to divide the logic wafer 20 to form multiple vertically distributed structures. The chip stack ST and the logic wafer 20 are vertically stacked from top to bottom.

In some structures, as shown in FIG. 15, the active surface of the logic chip 21 deviates from the chip stack ST.

In other structures, as shown in FIG. 16, the first chip 11 and the second chip 12 are connected to each other in a face-to-face hybrid bonding manner between the active surfaces S1.

In yet other structures, as shown in FIG. 17, the active side S 1 of the first chip 11 and the non-active surface S2 of the second chip 12 are connected in a hybrid bonding manner.

Optionally, in some embodiments, between multiple contact pads in the chip stack ST and between the logic chip 21 and the multiple contact pads on the bottommost chip of the chip stack ST, connections with each other are realized by vias 16 for communication. Here, the vias 16 may include, but is not limited to, through silicon vias (TSVs), etc.

In some embodiments, as shown in FIGS. 18 and 19, after the chip stack ST is bonded to the logic chip 21, the method further includes the following operation.

An encapsulation compound 4 is formed, and the encapsulation compound 4 is located above the logic chip 21 and the encapsulation compound 4 covers the cladding layer 30.

Here, the material of the encapsulation compound 4 may be, for example, epoxy resin, phenolic resin, polyimide, silica gel or spin-on silica glass, etc. The encapsulation compound 4 may protect the encapsulation structure from external dust, moisture and mechanical shock, thereby improving the reliability of the encapsulation structure.

An embodiment of the disclosure also provides a semiconductor device. As shown in FIGS. 7 and 18, the semiconductor device includes a logic chip 21, a chip stack ST and a cladding layer 30.

The chip stack ST includes multiple chips C stacked on the logic chip 21 in a vertical direction, and two adjacent ones of the chips C are connected to each other. The chip stack ST is formed by performing a cutting process on multiple wafers 10 vertically stacked.

The cladding layer 30 is located above the logic chip 21 and covers the side walls and the upper surface of the chip stack ST.

Here, the logic chip 21 may be one or more processors configured to communicate with the multiple chips C to access data from the chips C and store data in the multiple chips C. The logic chip 21 includes, but is not limited to, a GPU, an FPGA, an ASIC, a CPU, or other known electronic circuits used as processors. The chips C include, but are not limited to, dynamic random access memory (DRAM) chips.

In some embodiments, the multiple chips C include a first chip 11 and a second chip 12 connected to each other by a hybrid bonding member. The hybrid bonding member includes a first contact pad 13, a second contact pad 14, a first dielectric layer L1, and a second dielectric layer L2.

The first contact pad 13 is located on the surface of the first chip 11, and the second contact pad 14 is located on the surface of the second chip 12.

The first dielectric layer L1 is located on the periphery of the first contact pad 13, and the second dielectric layer L2 is located on the periphery of the second contact pad 14.

The first contact pad 13 and the second contact pad 14 are in contact bonding, and the first dielectric layer L1 and the second dielectric layer L2 are in contact bonding.

It can be appreciated that in the embodiments of the disclosure, compared with a conventional structure using a larger micro-bump for electrical connection, the mode of forming an electrical connection by one-to-one correspondence bonding between adjacent chips by means of hybrid bonding can effectively shorten the wiring distance between the adjacent chips, whereby the communication distance between the chips is shortened, the signal transmission efficiency can be effectively improved, and the communication time can be shortened.

In some embodiments, as shown in FIG. 17, the first dielectric layer L1 and the first contact pad 13 are formed on the active surface S1 of the first chip 11. The second dielectric layer L2 and the second contact pad 14 are formed on the non-active surface S2 of the second chip 12. The active surface S1 of the first chip 11 is bonded to the non-active surface S2 of the second chip 12. The active surface S1 is the side of the chip where a device layer is formed, and the non-active surface S2 is the opposite side of the active surface S1.

In this embodiment of the disclosure, the mode of forming an electrical connection by one-to-one corresponding bonding between adjacent chips by means of hybrid bonding can effectively shorten a gap between the adjacent chips, whereby the communication distance between the chips is shortened, the signal transmission efficiency can be effectively improved, and the communication time can be shortened.

In some embodiments, as shown in FIG. 16, the first dielectric layer L1 and the first contact pad 13 are located on the active surface S1 of the first chip 11. The second dielectric layer L2 and the second contact pad 14 are located on the active surface S1 of the second chip 12. The first chip 11 and the second chip 12 are bonded at the active surfaces S1 thereof. The active surface S1 is a side of the chip where a device layer is formed.

In this embodiment, by forming the first dielectric layer and the first contact pad on the active surface of the first chip and forming the second dielectric layer and the second contact pad on the active surface of the second chip, hybrid bonding is performed between the two chips in a face-to-face manner. That is, the adjacent chips are in a face-to-face hybrid bonding manner. It can be appreciated that this hybrid bonding and face-to-face bonding mode can further reduce the communication distance between the two adjacent chips, further improve the communication efficiency, and more effectively shorten the communication time as compared to other embodiments.

It should be noted that the disclosure only exemplifies some embodiments of bonding between chips. In actual operations, the bonding mode between the first chip and the second chip, and the positions where the first dielectric layer and the first contact pad, as well as the second dielectric layer and the second contact pad specifically formed on the first chip and the second chip may be flexibly adjusted according to actual situations.

In addition, in the drawings of the embodiments of the disclosure, diagrams of stacking and bonding four chips on a logic chip are shown by way of example only. The number of the chips may also be eight, twelve, and even other more or less numbers in an actual process. This is not particularly limited herein. The number of the chips may be flexibly adjusted as required.

In some embodiments, with continued reference to FIG. 15, it can be seen that the logic chip 21 and the chip stack ST are connected to each other by a first bonding member. The first bonding member includes a third contact pad 23 and a fourth contact pad 18.

The third contact pad 23 is located on the surface of the logic chip 21.

The fourth contact pad 18 is located on the lower surface of the chip C at the bottommost layer of the chip stack ST.

The logic chip 21 and the chip stack ST are in contact bonding through the third contact pad 23 and the fourth contact pad 18.

In some embodiments, the third contact pad 23 is located on the non-active surface S2 of the logic chip 21, the fourth contact pad 18 is located on the non-active surface S2 of the chip C at the bottommost layer of the chip stack ST, and the logic chip 21 and the chip stack ST are bonded between the non-active surfaces S2 thereof. The active surface S1 is the side of the logic chip 21 or of the chip C where a device layer is formed, and the non-active surface S2 is the opposite side of the active surface S1.

In embodiments of the disclosure, the positions where the third contact pad and the fourth contact pad are formed may be other possible combinations, and the disclosure is not limited thereto.

It can be appreciated that the active surface of the logic chip is arranged away from the chip stack effectively prevents heat from accumulating and avoids affecting the stability and reliability of the semiconductor device due to the excessive temperature. When the chip stack mounted on the structure is in hybrid bonding between the active surfaces of the chips in a face-to-face manner, the communication rate and the heat dissipation effect of the semiconductor device can both reach a better level.

Optionally, in some embodiments, as shown in FIG. 15, the semiconductor device further includes vias 16 that allow between multiple contact pads of the chip stack ST r and between the logic chip 21 and the multiple contact pads on the bottommost chip of the chip stack ST are interconnected with each other for communication. Here, the vias 16 may include, but is not limited to, TSVs, etc.

Optionally, in some embodiments, the semiconductor device further includes copper pillar bumps 22. The copper pillar bumps 22 are located on the surface of the logic chip 21 away from the chip stack ST. The copper pillar bumps 22 may be used for forming electrical connections between the semiconductor device and other devices, such as PCB boards.

In the manufacturing process of the semiconductor device, it is usually necessary to perform a cutting process on a prepared wafer to form multiple chips, it is easy to generate some substances such as particles during the cutting process, and it is difficult to completely remove all these substances even if a cleaning process is performed after the cutting process.

However, in the embodiments of the disclosure, by combining FIGS. 8b and 15-19, it can be seen that the cladding layer 30 wraps particles 5.

In some embodiments, the material of the cladding layer 30 includes a metal or a spin-on compound. Specifically, the metal material may include, but is not limited to, copper, etc. The spin-on compound may include, but is not limited to, spin-on glass (SOG), etc.

As shown in FIG. 18, the cladding layer 30 may be one layer of material. Specifically, the material may include, but is not limited to, a material with good thermal conductivity such as metal.

In this embodiment, when the material of the cladding layer is an electrically conductive material having good thermal conductivity and the electrically conductive material is in direct contact with the chip, the active surface of the chip, i.e. the side of the chip where a device layer is formed, needs to be away from the cladding layer.

As shown in FIG. 19, in some other embodiments, the cladding layer 30 includes a first sub-layer 31 and a second sub-layer 32, and the first sub-layer 31 is located between the second sub-layer 32 and the chip stack ST. The thermal diffusivity of the second sub-layer 32 is greater than the thermal diffusivity of the first sub-layer 31.

Optionally, the material of the first sub-layer 31 includes a spin-on compound and the material of the second sub-layer 32 includes a metal.

Here, the spin-on compound includes, but is not limited to, SOG, etc. The SOG may be an interlayer dielectric material that is spin-coated (similar to the spin-coating of a photoresist) onto the semiconductor device in a liquid state. Raw materials thereof may include, but are not limited to, hydrogen silsesquioxane polymer, siloxane solvent, etc. The material of the second sub-layer includes, but is not limited to, copper, etc. Although not limited thereto, the material of the second sub-layer may also be other materials having better thermal conductivity.

In an actual process, when the materials of the cladding layer and the second sub-layer are copper, the operation of performing an electroplating process includes the following operations.

The semiconductor device is immersed in an electroplating copper solution, and the semiconductor device includes a seed layer.

An electroplating copper layer is formed on the seed layer. The electroplating copper solution includes, but is not limited to, water, a copper supply source, an electrolyte material, etc.

It can be appreciated that in some structures not forming a cladding layer, substances such as the particles may move around, especially in the process of encapsulating and bonding with other functional chips, when these substances move therebetween, it is easy to cause the inclination of the upper chip and even cause the problem of poor contact of the device finally formed, thereby causing chip fault and even failure, and reducing the production yield.

Therefore, in this embodiment of the disclosure, the presence of the cladding layer can effectively prevent the above substances from moving during the subsequent transfer or encapsulation process, in which the movement of the substances may result in the inclination of the semiconductor device finally formed or a risk of poor contact, thereby improving the stability and reliability of the device finally formed, and being conductive to the improvement of the production yield.

In addition, in the conventional semiconductor device using the micro-bump structure, the information transmission rate is easily affected by heat dissipation condition. When heat inside the semiconductor device cannot be conducted away in time, the information transmission rate of the semiconductor device may be reduced, and the communication time may be prolonged. Furthermore, as the heat inside the semiconductor device accumulates, the stability and reliability of the semiconductor device are greatly affected.

In the embodiments of the disclosure, when the material of the cladding layer includes a metal material or other materials having relatively good thermal conductivity, heat generated inside the semiconductor device during operation can be conducted to the outside of the semiconductor device via the cladding layer. Therefore, in this embodiment of the disclosure, the semiconductor device can avoid the situation that the information transmission rate is reduced and the stability and reliability are reduced due to failure of timely heat dissipation, thus can effectively improve the stability and reliability problems of the semiconductor device.

In an actual process, with continued reference to FIGS. 18 and 19, the semiconductor device further includes an encapsulation compound 4. The encapsulation compound 4 is located above the logic chip 21 and the encapsulation compound 4 covers the cladding layer 30.

Here, the material of the encapsulation compound 4 may be, for example, epoxy resin, phenolic resin, polyimide, silica gel or spin-on silica glass, etc. The encapsulation compound 4 can protect the encapsulation structure from external dust, moisture and mechanical shock, thereby improving the reliability of the encapsulation structure.

It can be appreciated that in this embodiment of the disclosure, the encapsulation compound may be formed in any of the above structures mentioned in this embodiment of the disclosure.

In summary, in this embodiment of the disclosure, the presence of the cladding layer can effectively prevent the substances such as particles and powders generated during the cutting process from moving during the subsequent transfer or encapsulation process, in which the movement of the substances may result in the inclination of the semiconductor device finally formed or a risk of poor contact, thereby improving the stability and reliability of the device finally formed, and being conductive to the improvement of the production yield.

Moreover, when the material of the cladding layer includes a metal material or other materials having relatively good thermal conductivity, heat generated inside the semiconductor device during operation may be conducted to the outside of the semiconductor device via the cladding layer. Therefore, in this embodiment of the disclosure, the semiconductor device can avoid the situation that the information transmission rate is reduced and the stability and reliability are reduced due to not timely conduction of heat, and can effectively improve the stability and reliability problems of the semiconductor device.

Furthermore, in this embodiment of the disclosure, compared with a conventional structure using a larger micro-bump for electrical connection, the mode of forming an electrical connection by one-to-one correspondence bonding between the adjacent chips by means of hybrid bonding can effectively shorten the wiring distance between the adjacent chips, whereby the communication distance between the chips is shortened, the signal transmission efficiency can be effectively improved, and the communication time can be shortened.

Moreover, in the embodiments of the disclosure, by forming the first dielectric layer and the first contact pad on the active surface of the first chip and forming the second dielectric layer and the second contact pad on the active surface of the second chip, hybrid bonding is performed between the two chips in a face-to-face manner. That is, the adjacent chips are in a face-to-face hybrid bonding manner. It can be appreciated that this hybrid bonding and face-to-face bonding mode can reduce the communication distance between the two adjacent chips, further improve the communication efficiency, and more effectively shorten the communication time as compared to other embodiments.

In addition, in the structure where the active surface of the logic chip is away from the chip stack, heat can be effectively prevented from accumulating, thereby avoiding affecting the stability and reliability of the semiconductor device due to the excessive temperature. When the chip stack mounted on the structure is in hybrid bonding between the active surfaces of the chips in a face-to-face manner, the communication rate and the heat dissipation effect of the semiconductor device can both reach better levels.

It should be noted that the method for manufacturing a semiconductor device and the semiconductor device provided by the embodiments of the disclosure may be applied to any integrated circuit including such structures, including but not limited to vertical integration of processed integrated circuits, for 3D SOC, micro-pad encapsulation, replacement of the low-cost and high-performance flip chip bonding, wafer level encapsulation, thermal management, and unique device structures (e.g. metal base devices). Applications further include, but are not limited to, integrated circuits (such as back lighting image sensors), RF front ends, micro-electrical mechanical structures (MEMS) (including but not limited to pico-projectors and gyroscopes), 3D stack memories (including but not limited to hybrid memory blocks), high band width memories, DIRAM, 2.5D (including but not limited to FPGA tilted on an interposer), and products in which these circuits are used (including but not limited to mobile phones and other mobile devices, laptop computers, and servers).

The technical features in the technical solutions described in the embodiments may be arbitrarily combined without conflict. Those skilled in the art can change the order of the operations of the above-mentioned forming method without departing from the scope of the disclosure, various operations in the embodiments of the disclosure may be performed at the same time without conflict, and some operations may also be performed in a reversed order.

The above are only preferred embodiments of the disclosure, and are not used to limit the protection scope of the disclosure. Any modifications, equivalent replacements and improvements and the like made within the spirit and principle of the disclosure shall be included within the protection scope of the disclosure.

### INDUSTRIAL APPLICABILITY

The method for manufacturing a semiconductor device provided by the embodiment of the disclosure can significantly improve the stability and reliability of the semiconductor device finally formed. In addition, without cutting off the carrier while performing the first cutting process in the embodiments of the disclosure provides the possibility that the cladding layer may be simultaneously formed on the side walls and the upper surfaces of the multiple chip stacks, optimizes the process flow, and can effectively improve the production efficiency.

1. A method for manufacturing a semiconductor device, comprising:
providing a carrier;
providing multiple wafers each comprising multiple chips;
stacking the multiple wafers on the carrier sequentially in a vertical direction, and bonding the chips respectively disposed on two adjacent ones of the wafers in a one-to-one correspondence;
performing a first cutting process on the multiple wafers to form multiple cutting slots located above the carrier and penetrating through the multiple wafers, the multiple wafers being divided into multiple chip stacks by the cutting slots, each of the chip stacks comprising multiple chips stacked in the vertical direction, and the carrier enabling the multiple chip stacks to be in an un-separated state;
forming a cladding layer covering a side wall and an upper surface of at least one chip stack; and
performing a second cutting process on the cladding layer along the cutting slots to form multiple chip stacks having side walls and upper surfaces covered with the cladding layer.

2. The method according to claim 1, wherein after performing the second cutting process, the method further comprises:
separating the carrier from the chip stack;
providing a logic wafer comprising at least one logic chip; and
bonding the chip stack to the logic chip.

3. The method according to claim 1, wherein forming the cladding layer comprises:
forming a seed layer on the chip stack, the seed layer covering the side wall and the upper surface of the chip stack, wherein an active surface of the chip located at a topmost layer of the chip stack faces downwards, and the active surface is a side of the wafer where a device layer is formed; and
performing an electroplating process to form a cladding layer on the seed layer, the cladding layer covering the seed layer.

4. The method according to claim 1, wherein forming the cladding layer comprises:
performing a coating process to form a first sub-layer on the side wall and the upper surface of the chip stack;
forming a seed layer on the first sub-layer; and
performing an electroplating process to form a second sub-layer on the seed layer, the second sub-layer covering the seed layer.

5. The method according to claim 1, wherein,
performing the first cutting process on the multiple wafers comprises:
performing the first cutting process on the multiple wafers by using a wafer cutting knife and/or a cutting line to the form multiple cutting slots located above the carrier and penetrating through the multiple wafers, the multiple wafers being divided into multiple chip stacks by the cutting slots; and
performing the second cutting process on the cladding layer along the cutting slots comprises:
performing the second cutting process on the cladding layer by using a grinding wheel, a wafer cutting knife, a cutting line, and/or a laser cutting process to form the multiple chip stacks having the side walls and upper surfaces covered with the cladding layer.

6. The method according to claim 1, wherein,
providing the multiple wafers each comprising multiple chips comprises:
providing a first wafer comprising multiple first chips and a second wafer comprising multiple second chips; and
stacking the multiple wafers on the carrier sequentially in the vertical direction and bonding the chips respectively disposed on the adjacent wafers in a one-to-one correspondence comprises:
forming at least one first contact pad and at least one second contact pad on a surface of the first wafer and a surface of the second wafer, respectively, and forming a first dielectric layer located on periphery of the first contact pad and a second dielectric layer located on periphery of the second contact pad;
stacking the first wafer and the second wafer above the carrier sequentially such that the first contact pad and the second contact pad are butted; and
performing a bonding process such that the first contact pad and the second contact pad are bonded and the first dielectric layer and the second dielectric layer are bonded to form a hybrid bonding member.

7. The method according to claim 6, wherein forming at least one first contact pad and at least one second contact pad on the surface of the first wafer and the surface of the second wafer, respectively, and forming the first dielectric layer located on the periphery of the first contact pad and the second dielectric layer located on the periphery of the second contact pad comprises:
forming the first dielectric layer on an active surface of the first wafer;
forming at least one first via in the first dielectric layer;
forming the first contact pad in the first via, the first contact pad being connected to the first chip in a one-to-one correspondence;
forming the second dielectric layer on an active surface of the second wafer;
forming at least one second via in the second dielectric layer; and
forming the second contact pad in the second via, the second contact pad being connected to the second chip in a one-to-one correspondence,
wherein the active surface is a side of the wafer where a device layer is formed.

8. The method according to claim 6, wherein forming at least one first contact pad and at least one second contact pad on the surface of the first wafer and the surface of the second wafer, respectively, and forming the first dielectric layer located on the periphery of the first contact pad and the second dielectric layer located on the periphery of the second contact pad comprises:
forming the first dielectric layer on an active surface of the first wafer;
forming at least one first via in the first dielectric layer;
forming the first contact pad in the first via, the first contact pad being connected to the first chip in a one-to-one correspondence;
forming the second dielectric layer on a non-active surface of the second wafer;
forming at least one second via in the second dielectric layer; and
forming the second contact pad in the second via, the second contact pad being connected to the second chip in a one-to-one correspondence,
wherein the active surface is a side of the wafer where a device layer is formed, and the non-active surface is an opposite side of the active surface.

9. The method according to claim 2, wherein bonding the chip stack to the logic chip comprises:
forming at least one third contact pad on a surface of the logic wafer, the third contact pad being connected to the logic chip in a one-to-one correspondence;
forming a fourth contact pad on a lower surface of the chip at a bottommost layer of the chip stack;
arranging the chip stack above the logic chip, the third contact pad being butted with the fourth contact pad; and
performing a bonding process such that the third contact pad and the fourth contact pad are bonded.

10. The method according to claim 2, wherein after bonding the chip stack to the logic chip, the method further comprises:
forming an encapsulation compound located above the logic chip and covering the cladding layer.

11. A semiconductor device, comprising:
a logic chip;
a chip stack, comprising multiple chips stacked on the logic chip in a vertical direction, two adjacent ones of the chips being connected with each other, wherein the chip stack is formed by performing a cutting process on multiple vertically stacked wafers; and
a cladding layer, located above the logic chip and covering a side wall and an upper surface of the chip stack.

12. The semiconductor device according to claim 11, wherein a material of the cladding layer comprises a metal or a spin-on compound.

13. The semiconductor device according to claim 11, wherein the cladding layer comprises a first sub-layer and a second sub-layer, the first sub-layer being located between the second sub-layer and the chip stack, wherein thermal diffusivity of the second sub-layer is greater than thermal diffusivity of the first sub-layer.

14. The semiconductor device according to claim 13, wherein a material of the first sub-layer comprises a spin-on compound and a material of the second sub-layer comprises a metal.

15. The semiconductor device according to claim 11, wherein the multiple chips comprise a first chip and a second chip connected with each other by a hybrid bonding member which comprises:
a first contact pad, located on a surface of the first chip, and a second contact pad located on a surface of the second chip; and
a first dielectric layer, located on periphery of the first contact pad and a second dielectric layer located on periphery of the second contact pad,
wherein the first contact pad and the second contact pad are in contact bonding and the first dielectric layer and the second dielectric layer are in contact bonding.

16. The semiconductor device according to claim 15, wherein the first dielectric layer and the first contact pad are located on an active surface of the first chip, the second dielectric layer and the second contact pad are located on an active surface of the second chip, and the first chip and the second chip are bonded at the active surfaces of the first and second chips, wherein the active surface is a side of the chip where a device layer is formed.

17. The semiconductor device according to claim 15, wherein the first dielectric layer and the first contact pad are formed on an active surface of the first chip, the second dielectric layer and the second contact pad are formed on a non-active surface of the second chip, and the active surface of the first chip is bonded to the non-active surface of the second chip, wherein the active surface is a side of the chip where a device layer is formed, and the non-active surface is an opposite side of the active surface.

18. The semiconductor device according to claim 11, wherein the logic chip and the chip stack are connected with each other by a first bonding member which comprises:
a third contact pad, located on a surface of the logic chip; and
a fourth contact pad, located on a lower surface of the chip at a bottommost layer of the chip stack,
wherein the logic chip and the chip stack are in contact bonding through the third contact pad and the fourth contact pad.

19. The semiconductor device according to claim 18, wherein the third contact pad is located on a non-active surface of the logic chip, the fourth contact pad is located on a non-active surface of the chip at the bottommost layer of the chip stack, and the logic chip and the chip stack are bonded at the non-active surfaces of the logic chip and the chip stack, wherein an active surface is a side of the logic chip or the chip where a device layer is formed, and the non-active surface is an opposite side of the active surface.

20. The semiconductor device according to claim 11, further comprising an encapsulation compound located above the logic chip and covering the cladding layer.
